(19) United States
(12) Patent Application Publication
(10) Pub. No.: US 2025/0024668 A1
(43) Pub. Date: Jan. 16, 2025

(54) ANTIFUSE-TYPE MEMORY WITH FIN FIELD-EFFECT TRANSISTOR

(71) Applicant: eMemory Technology Inc., Hsin-Chu (TW)

(72) Inventors: Yi-Hung LI, Hsinchu County (TW); Chun-Hung LIN, Hsinchu County (TW)

(21) Appl. No.: 18/670,762

(22) Filed: May 22, 2024

Related U.S. Application Data
(60) Provisional application No. 63/526,481, filed on Jul. 13, 2023.

(51) Int. Cl. H10B 20/25; H01L 29/417; H01L 29/78

(52) U.S. Cl. CPC H10B 20/25; H01L 29/41791; H01L 29/7851

(57) ABSTRACT

An antifuse-type memory includes a first memory cell. The first memory cell includes a first select transistor, a first following transistor and a first antifuse transistor. A first drain/source terminal of the first select transistor is connected with a first bit line. A gate terminal of the first select transistor is connected with a first word line. A first drain/source terminal of the first following transistor is connected with a second drain/source terminal of the first select transistor. A gate terminal of the first following transistor is connected with a first following control line. The first antifuse transistor includes a first fin, a first gate structure, a first drain/source contact layer and a second drain/source contact layer. The first gate structure includes a first gate dielectric layer and a first gate layer. The first gate layer is connected with a first antifuse control line.

This application claims the benefit of U.S. provisional application Ser. No. 63/526,481, filed Jul. 13, 2023, the subject matters of which are incorporated herein by references.

### FIELD OF THE INVENTION

The present invention relates to an antifuse-type memory, and more particularly to an antifuse-type memory with fin field-effect (FinFET) transistors.

### BACKGROUND OF THE INVENTION

As is well known, a one time programming memory (also referred as an OTP memory) is one of the non-volatile memories. The OTP memory comprises plural one time programming memory cells (also referred as OTP memory cells). The OTP memory cell can be programmed once. After the OTP memory cell is programmed, the stored data in the OTP memory cell fails to be modified.

For example, an antifuse-type memory is one kind of OTP memory. Before the memory cell of the antifuse-type memory is programmed, the memory cell of the antifuse-type memory is in a high-resistance storage state. After the memory cell of the antifuse-type memory is programmed, the memory cell of the antifuse-type memory is in a low-resistance storage state. After the memory cell of an antifuse-type memory is programmed, the stored data in the memory cell cannot be changed.

### SUMMARY OF THE INVENTION

An embodiment of the present invention provides an antifuse-type memory is provided. The antifuse-type memory includes a first memory cell. The first memory cell is constructed on a semiconductor substrate. The first memory cell includes a first select transistor, a first following transistor and a first antifuse transistor. A first drain/source terminal of the first select transistor is connected with a first bit line. A gate terminal of the first select transistor is connected with a first word line. A first drain/source terminal of the first following transistor is connected with a second drain/source terminal of the first select transistor. A gate terminal of the first following transistor is connected with a first following control line. The first antifuse transistor includes a first fin, a first gate structure, a first drain/source contact layer and a second drain/source contact layer. The first gate structure includes a first gate dielectric layer and a first gate layer. The first gate dielectric layer covers a top surface and two lateral surfaces of a central region of the first fin. The first gate dielectric layer is covered by the first gate layer. The first gate layer is connected with a first antifuse control line. The first drain/source contact layer is electrically connected with a first terminal of the first fin. The first drain/source contact layer is connected with a second drain/source terminal of the first following transistor. The second drain/source terminal is electrically connected with a second terminal of the first fin. If the first bit line receives a ground voltage, the first word line receives an on voltage, the first following control line receives a conducting voltage and the first antifuse control line receives a program voltage when a program action is performed, the first gate dielectric layer of the first antifuse transistor is ruptured. Consequently, the first memory cell is programmed into a low-resistance storage state.

Numerous objects, features and advantages of the present invention will be readily apparent upon a reading of the following detailed description of embodiments of the present invention when taken in conjunction with the accompanying drawings. However, the drawings employed herein are for the purpose of descriptions and should not be regarded as limiting.

### BRIEF DESCRIPTION OF THE DRAWINGS

The above objects and advantages of the present invention will become more readily apparent to those ordinarily skilled in the art after reviewing the following detailed description and accompanying drawings, in which:

FIGS. 1A to 1L are schematic perspective views and cross-sectional views illustrating a process of manufacturing a FinFET transistor according to an embodiment of the present invention, wherein the cross-sectional views are taken along the dashed line AB;

FIG. 2 is a schematic perspective view illustrating an antifuse-type memory according to a first embodiment of the present invention;

FIG. 3A schematically illustrates associated bias voltages for performing a program action on the memory cells of the antifuse-type memory according to the first embodiment of the present invention;

FIG. 3B schematically illustrates associated bias voltages for performing a read action on the memory cells of the antifuse-type memory according to the first embodiment of the present invention;

FIG. 4 is a schematic perspective view illustrating an antifuse-type memory according to a second embodiment of the present invention;

FIG. 5A schematically illustrates associated bias voltages for performing a program action on the memory cells of the antifuse-type memory according to the second embodiment of the present invention;

FIG. 5B schematically illustrates associated bias voltages for performing a read action on the memory cells of the antifuse-type memory according to the second embodiment of the present invention; and

FIG. 6 is a schematic cross-sectional view illustrating another exemplary well structure of the antifuse-type memory.

### DETAILED DESCRIPTION OF PREFERRED EMBODIMENTS

The present invention provides an antifuse-type memory with fin field-effect (FinFET) transistors. Since the antifuse transistor receives a higher operation voltage, the technology of the present invention can be applied to the antifuse transistor operated at the high operation voltage.

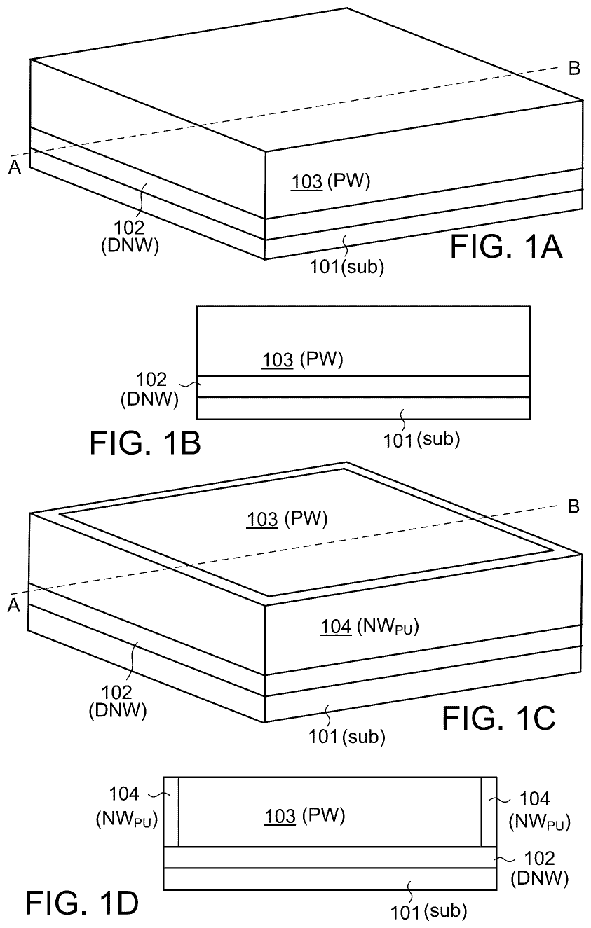

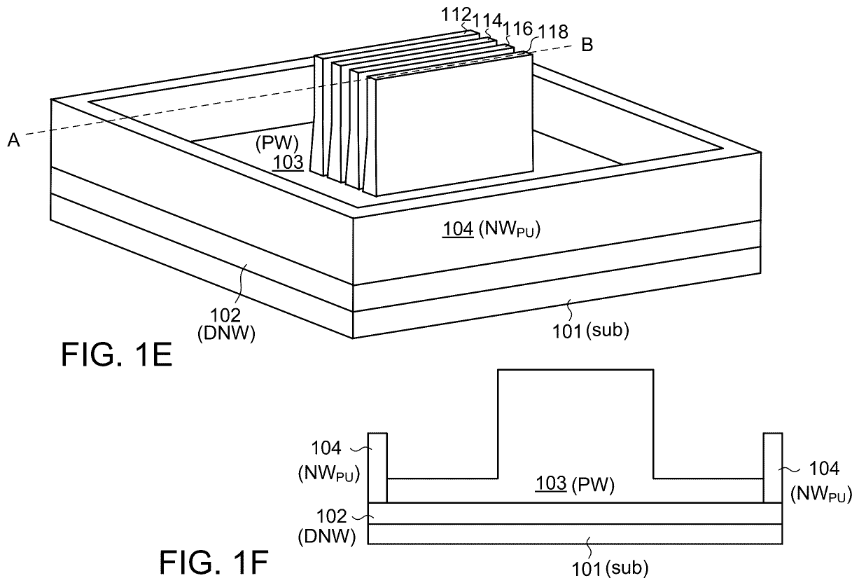

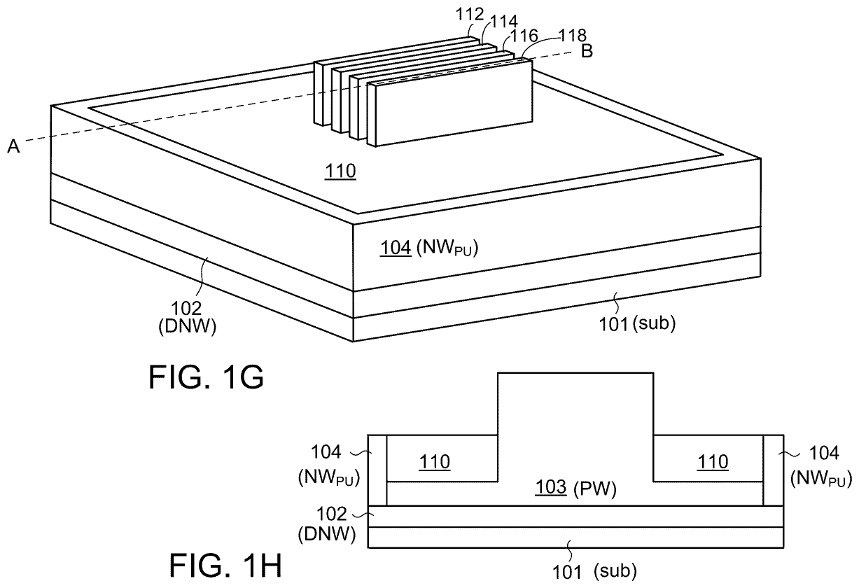

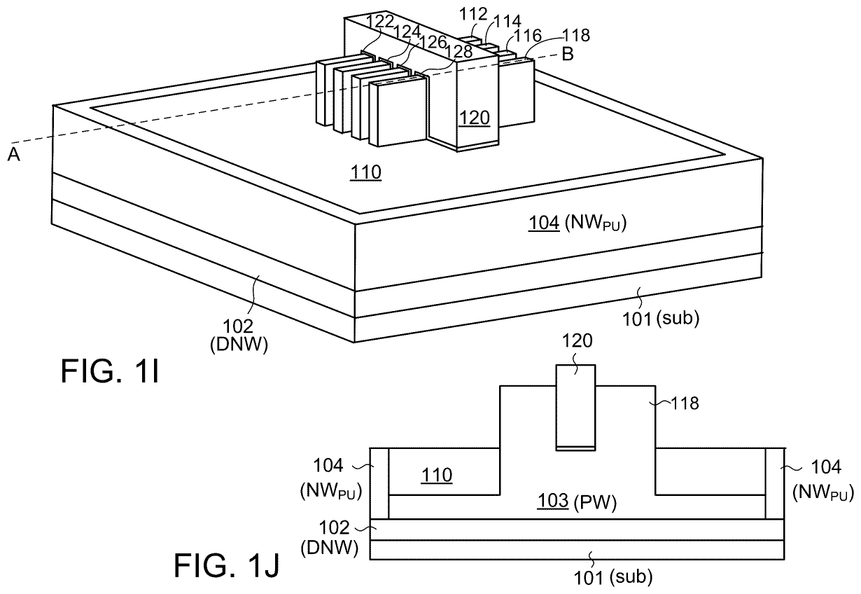

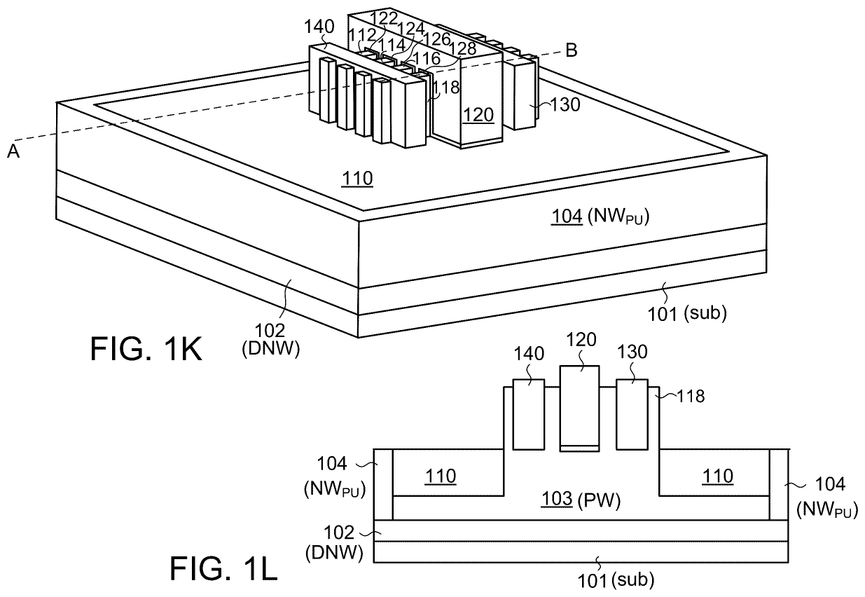

FIGS. 1A to 1L are schematic perspective views and cross-sectional views illustrating a process of manufacturing a FinFET transistor according to an embodiment of the present invention, wherein the cross-sectional views are taken along the dashed line AB.

Please refer to FIGS. 1A and 1B. Firstly, a P-well region (PW) 103 and a deep N-well region (DNW) 102 are formed in a semiconductor substrate (sub) 101. The P-well region (PW) 103 is formed in the surface of the semiconductor substrate (sub) 101. The deep N-well region (DNW) 102 is located under the P-well region (PW) 103 and contacted with the P-well region (PW) 103. For example, the semiconductor substrate (sub) 101 is a P-type substrate (P-substrate).

Please refer to FIGS. 1C and 1D. Then, a pickup N-well region (NW_{PU}) 104 is formed around the P-well region (PW) 103. The bottom side of the pickup N-well region (NW_{PU}) 104 is contacted with the deep N-well region (DNW) 102. The top side of the pickup N-well region (NW_{PU}) 104 is exposed to the surface of the semiconductor substrate (sub) 101. That is, in the well structure, the lateral side of the P-well region (PW) 103 is contacted with the pickup N-well region (NW_{PU}) 104, and the bottom side of the P-well region (PW) 103 is contacted with the deep N-well region (DNW) 102. In other words, the lateral side and the bottom side of the P-well region (PW) 103 are completely surrounded by the pickup N-well region (NW_{PU}) 104 and the deep N-well region (DNW) 102.

Please refer to FIGS. 1E and 1F. Then, the pickup N-well region (NW_{PU}) 104 and the P-well region (PW) 103 are etched. Consequently, plural protrusion structures are formed on the P-well region (PW) 103. These protrusion structures are protruded from the surface of the P-well region (PW) 103.

Please refer to FIGS. 1G and 1H. Then, an isolation layer 110 is formed on the region that is located over the P-well region (PW) 103 and enclosed by the pickup N-well region (NW_{PU}) 104. In other words, the surface of the P-well region (PW) 103 and the lower parts of the protrusion structures are covered by the isolation layer 110. The regions of the protrusion structures uncovered by the isolation layer 110 are formed as fins 112, 114, 116 and 118. In other words, these fins 112, 114, 116 and 118 are extended from the semiconductor substrate (sub) 101, and these fins 112, 114, 116 and 118 are protruded over the surface of the isolation layer 110.

Optionally, an ion implantation process is performed on the fins 112, 114, 116 and 118 in the resulting structure of FIG. 1G. Consequently, the fins 112, 114, 116 and 118 may have various dopant types. For example, in an embodiment, the fins 112, 114, 116 and 118 are all N-doped regions. In another embodiment, the fins 112, 114, 116 and 118 are all P-doped regions. Alternatively, the fins 112, 114, 116 and 118 are all undoped regions.

Please refer to FIGS. 1I and 1J. Then, a gate structure is formed over the isolation layer 110 to cover the central regions of the fins 112, 114, 116 and 118. Moreover, the two side regions of the fins 112, 114, 116 and 118 are exposed. The gate structure comprises a gate layer 120 and plural gate dielectric layers 122, 124, 126 and 128. The gate dielectric layers 122, 124, 126 and 128 cover the top surfaces and the lateral surfaces of the central regions of the fins 112, 114, 116 and 118, respectively. In an embodiment, the gate dielectric layers 122, 124, 126 and 128 are contacted with each other. Moreover, the gate layer 120 covers the gate dielectric layers 122, 124, 126 and 128.

Optionally, an ion implantation process is performed on the fins 112, 114, 116 and 118 in the resulting structure of FIG. 1I. Consequently, the fins 112, 114, 116 and 118 may have various dopant types. For example, in an embodiment, the first side regions and the second side regions of the fins 112, 114, 116 and 118 are all N-doped regions. In another embodiment, the first side regions and the second side regions of the fins 112, 114, 116 and 118 are all P-doped regions.

Please refer to FIGS. 1K and 1L. Then, two drain/source contact layers 130 and 140 are formed. The drain/source contact layer 130 is contacted with the top surfaces and the lateral surfaces of the first side regions of the fins 112, 114, 116 and 118. The drain/source contact layer 140 is contacted with the top surfaces and the lateral surfaces of the first side regions of the fins 112, 114, 116 and 118. The drain/source contact layer 130 is made of metallic material and contacted with the first side regions of the fins 112, 114, 116 and 118. The drain/source contact layer 140 is made of metallic material and contacted with the second side regions of the fins 112, 114, 116 and 118. Consequently, the two drain/source contact layers 130 and 140, the gate structure and the fins 112, 114, 116 and 118 are collaboratively formed as a FinFET transistor. In addition, the central regions of the fins 112, 114, 116 and 118 may be considered as a channel region of the FinFET transistor.

As shown in FIG. 1L, the well structure includes a P-type region and an N-type region. The pickup N-well region (NW_{PU}) 104 and the deep N-well region (DNW) 102 are collaboratively formed as the N-type region of the well structure. The P-well region (PW) 103 is formed as the P-type region of the well structure. That is, the lateral side and the bottom side of the P-type region of the well structure are contacted with the N-type region of the well structure, and the lateral side and the bottom side of the P-type region of the well structure are enclosed by the N-type region of the well structure. The FinFET transistor is constructed over the P-type region of the well structure. In addition, the region that is arranged between the pickup N-well region (NW_{PU}) 104 and the FinFET transistor and located over the P-well region (PW) 103 is covered by the isolation layer 110.

In this embodiment, the FinFET transistor is constructed over the P-well region (PW) 103. After the first side regions and the second side regions of the fins 112, 114, 116 and 118 are doped as an N-doped region, the FinFET transistor is an N-type transistor.

It is noted that the FinFET transistor using the technology of the present invention is not restricted to the N-type transistor. For example, in another embodiment, the FinFET transistor is a P-type transistor. Similarly, the well structure includes a P-type region and an N-type region. The lateral side and the bottom side of the N-type region of the well structure are contacted with the P-type region of the well structure, and the lateral side and the bottom side of the N-type region of the well structure are enclosed by the P-type region of the well structure. The FinFET transistor is constructed over the N-type region of the well structure. After the first side regions and the second side regions of the fins 112, 114, 116 and 118 are doped as a P-doped region, the FinFET transistor is a P-type transistor.

In FIG. 1L, the FinFET transistor comprises four fins 112, 114, 116 and 118. It is noted that the number of fins in the FinFET transistor is not restricted. For example, the FinFET transistor comprises N fins, wherein N is a positive integer.

Furthermore, plural FinFET transistors are formed over the semiconductor substrate (sub) 101 and collaboratively formed as a memory cell of the antifuse-type memory, and plural memory cells are collaboratively formed as an array structure.

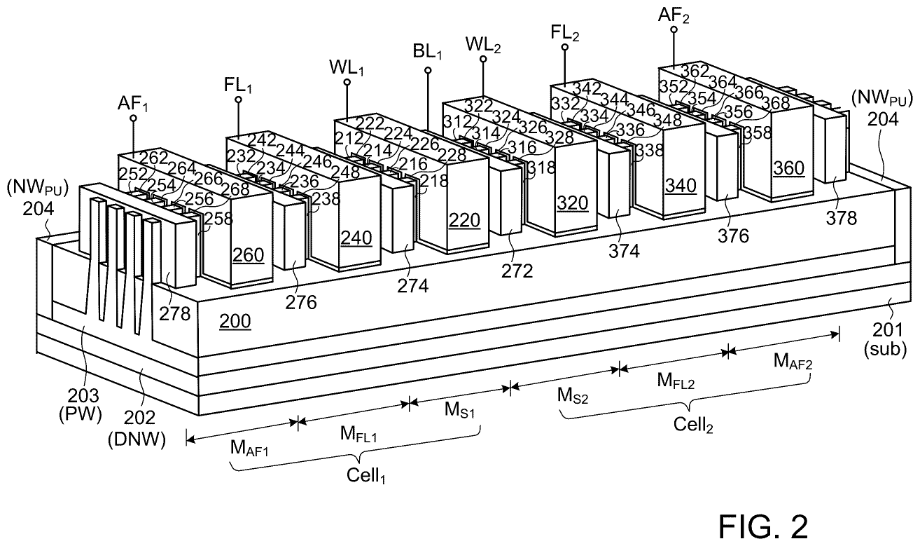

FIG. 2 is a schematic perspective view illustrating an antifuse-type memory according to a first embodiment of the present invention. As shown in FIG. 2, the antifuse-type memory comprises two memory cells Cell₁ and Cell₂. Like the structure of FIG. 1K, the FinFET transistors of the two memory cells Cell₁ and Cell₂ are constructed over a P-well region (PW) 203 within a semiconductor substrate (sub) 201 and enclosed by a pickup N-well region (NW_{PU}) 204. Furthermore, the lateral side of the P-well region (PW) 203 is contacted with the pickup N-well region (NW_{PU}) 204, and the bottom side of the P-well region (PW) 203 is contacted with a deep N-well region (DNW) 202. The pickup N-well region (NW_{PU}) 204 and the deep N-well region (DNW) 202 are collaboratively formed as the N-type region of the well structure. The P-well region (PW) 203 is formed as the P-type region of the well structure. That is, the lateral side and the bottom side of the P-type region of the well structure are enclosed by the N-type region of the well structure. In addition, the region that is arranged between the pickup N-well region (NW_{PU}) 204 and the FinFET transistor and located over the P-well region (PW) 203 is covered by an isolation layer 200.

As shown in FIG. 2, the two memory cells Cell₁ and Cell₂ of the antifuse-type memory are formed as a 2×1 array structure. The array structure is constructed over the P-well region (PW) 203 within a semiconductor substrate (sub) 201 and enclosed by the pickup N-well region (NW_{PU}) 204.

In this embodiment, each of the two memory cells Cell₁ and Cell₂ comprises three FinFET transistors. The structure of each of the three FinFET transistors is similar to that of FIG. 1K, and not redundantly described herein. As shown in FIG. 2, the memory cell Cell₁ comprises a select transistor M_{S1}, a following transistor M_{FL1} and an antifuse transistor M_{AF1}.

In the memory cell Cell₁, the select transistor M_{S1} comprises a drain/source contact layer 272, a drain/source contact layer 274, a gate structure and four fins 212, 214, 216 and 218. The gate structure covers the top surfaces and the lateral surfaces of the central regions of the fins 212, 214, 216 and 218. The gate structure comprises four gate dielectric layers 222, 224, 226, 228 and a gate layer 220. The gate dielectric layers 222, 224, 226 and 228 cover the top surfaces and the lateral surfaces of the central regions of the fins 212, 214, 216 and 218, respectively. The gate layer 220 covers the gate dielectric layers 222, 224, 226 and 228. The drain/source contact layer 272 is electrically contacted with the top surfaces and the lateral surfaces of the first side regions of the fins 212, 214, 216 and 218. The drain/source contact layer 274 is electrically contacted with the top surfaces and the lateral surfaces of the second side regions of the fins 212, 214, 216 and 218. In other words, the first terminals of the fins 212, 214, 216 and 218 are electrically connected with the drain/source contact layer 272, and the second terminals of the fins 212, 214, 216 and 218 are electrically connected with the drain/source contact layer 274. Moreover, the drain/source contact layer 272 is connected with a bit line BL₁, and the gate layer 220 is connected with a word line WL₁.

The following transistor M_{FL1} comprises the drain/source contact layer 274, a drain/source contact layer 276, a gate structure and four fins 232, 234, 236 and 238. The gate structure covers the top surfaces and the lateral surfaces of the central regions of the fins 232, 234, 236 and 238. The gate structure comprises four gate dielectric layers 242, 244, 246, 248 and a gate layer 240. The gate dielectric layers 242, 244, 246 and 248 cover the top surfaces and the lateral surfaces of the central regions of the fins 232, 234, 236 and 238, respectively. The gate layer 240 covers the gate dielectric layers 232, 234, 236 and 238. The drain/source contact layer 274 is electrically contacted with the top surfaces and the lateral surfaces of the first side regions of the fins 232, 234, 236 and 238. The drain/source contact layer 276 is electrically contacted with the top surfaces and the lateral surfaces of the second side regions of the fins 232, 234, 236 and 238. In other words, the first terminals of the fins 232, 234, 236 and 238 are electrically connected with the drain/source contact layer 274, and the second terminals of the fins 232, 234, 236 and 238 are electrically connected with the drain/source contact layer 276. Moreover, the gate layer 240 is connected with a following control line FL₁. The drain/source contact layer 274 is shared by the select transistor M_{S1} and the following transistor M_{FL1}.

The antifuse transistor M_{AF1} comprises the drain/source contact layer 276, a drain/source contact layer 278, a gate structure and four fins 252, 254, 256 and 258. The gate structure covers the top surfaces and the lateral surfaces of the central regions of the fins 252, 254, 256 and 258. The gate structure comprises four gate dielectric layers 262, 264, 266, 268 and a gate layer 260. The gate dielectric layers 262, 264, 266 and 268 cover the top surfaces and the lateral surfaces of the central regions of the fins 252, 254, 256 and 258, respectively. The gate layer 260 covers the gate dielectric layers 262, 264, 266 and 268. The drain/source contact layer 276 is electrically contacted with the top surfaces and the lateral surfaces of the first side regions of the fins 252, 254, 256 and 258. The drain/source contact layer 278 is electrically contacted with the top surfaces and the lateral surfaces of the second side regions of the fins 252, 254, 256 and 258. In other words, the first terminals of the fins 252, 254, 256 and 258 are electrically connected with the drain/source contact layer 276, and the second terminals of the fins 252, 254, 256 and 258 are electrically connected with the drain/source contact layer 278. Moreover, the gate layer 260 is connected with an antifuse control line AF₁. The drain/source contact layer 276 is shared by the following transistor M_{FL1} and the antifuse transistor M_{AF1}.

The structures of the memory cell Cell₁ and the memory cell Cell₂ are identical. Briefly, the memory cell Cell₂ comprises a select transistor M_{S2}, a following transistor M_{FL2} and an antifuse transistor M_{AF2}.

The select transistor M_{S2} comprises a drain/source contact layer 372, a drain/source contact layer 374, a gate structure and four fins 312, 314, 316 and 318. The gate structure of the select transistor M_{S2} comprises four gate dielectric layers 322, 324, 326, 328 and a gate layer 320. In addition, the gate layer 320 is connected with a word line WL₂.

The following transistor M_{FL2} comprises the drain/source contact layer 374, a drain/source contact layer 376, a gate structure and four fins 332, 334, 336 and 338. The gate structure of the following transistor M_{FL2} comprises four gate dielectric layers 342, 344, 346, 348 and a gate layer 340. In addition, the gate layer 340 is connected with a following control line FL₂.

The antifuse transistor M_{AF2} comprises the drain/source contact layer 376, a drain/source contact layer 378, a gate structure and four fins 352, 354, 356 and 358. The gate structure of the antifuse transistor M_{AF2} comprises four gate dielectric layers 362, 364, 366, 368 and a gate layer 360. In addition, the gate layer 360 is connected with an antifuse control line AF₂.

Please refer to FIG. 2 again. In order to allow the array structure of the antifuse-type memory of the first embodiment to perform the program action and the read action normally, the memory cell Cell₁ is further equipped with a dummy FinFET transistor on the left side. The dummy FinFET transistor is connected with the left side of the antifuse transistor M_{AF1}. In addition, the drain/source contact layer 278 is shared by the dummy FinFET transistor and the antifuse transistor M_{AF1} the. Similarly, the memory cell Cell₂ is further equipped with a dummy FinFET transistor on the right side. The dummy FinFET transistor is connected with the right side of the antifuse transistor M_{AF2}. In addition, the drain/source contact layer 378 is shared by the dummy FinFET transistor and the antifuse transistor M_{AF2}. The connecting relationship between the antifuse transistor M_{AF1} and the dummy FinFET transistor is similar to the connecting relationship between the following transistor M_{FL1} and the antifuse transistor M_{AF1}, and not redundantly described herein.

Generally, when the program action or the read action is performed, no bias voltages are provided to the three terminals in each of the two dummy FinFET transistors. Consequently, the two dummy FinFET transistors are turned off (i.e., disabled). Due to the above connecting relationships in the array structure of the antifuse-type memory, the left side of the memory cell Cell₁ can be connected with another memory cell through the adjacent dummy FinFET transistor. Similarly, the right side of the memory cell Cell₂ can be connected with another memory cell through the adjacent dummy FinFET transistor. Consequently, the size of the array structure of the antifuse-type memory in the first embodiment can be expanded.

Please refer to FIG. 2 again. The first terminal of the fin 258 of the antifuse transistor M_{AF1} is electrically connected with the second terminal of the fin 238 of the following transistor M_{FL1}. The first terminal of the fin 238 of the following transistor M_{FL1} is electrically connected with the second terminal of the fin 218 of the select transistor M_{S1}. The connecting relationships between the other fins of the antifuse transistor M_{AF1}, the following transistor M_{FL1}, and the select transistor M_{S1} are similar to the connecting relationships between the fins 258, 238 and 218, and not redundantly described herein.

In an embodiment, the fin 218 of the select transistor M_{S1}, the fin 238 of the following transistor M_{FL1} and the fin 258 of the antifuse transistor M_{AF1} are integrated as a long fin on the semiconductor substrate. The long fin is divided into three parts. That is, the first part of the long fin is the fin 218 of the select transistor M_{S1}, the second part of the long fin is the fin 238 of the following transistor M_{FL1}, and the third part of the long fin is the fin 258 of the antifuse transistor M_{AF1}. That is, the fin 218 of the select transistor M_{S1}, the fin 238 of the following transistor M_{FL1} and the fin 258 of the antifuse transistor M_{AF1} are integrally formed. Similarly, the corresponding fins of the other fins of the select transistor M_{S1}, the following transistor M_{FL1} and the antifuse transistor M_{AF1} are integrally formed.

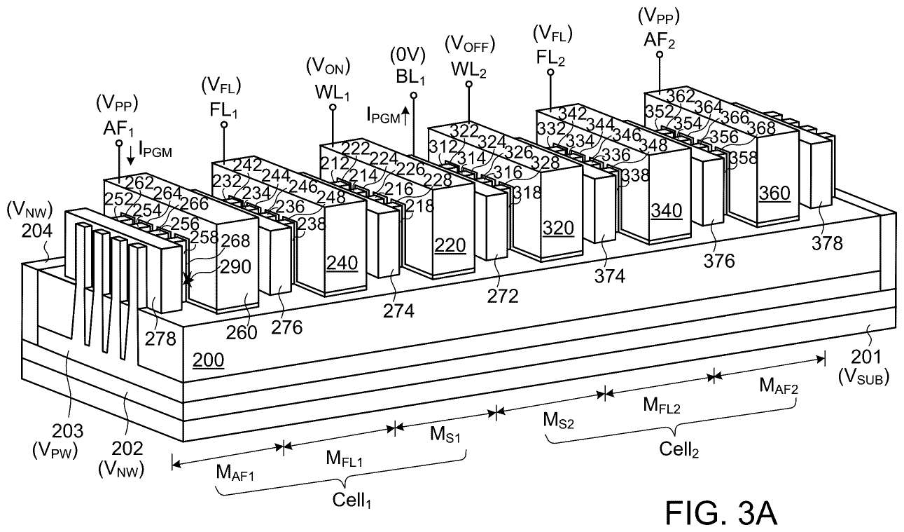

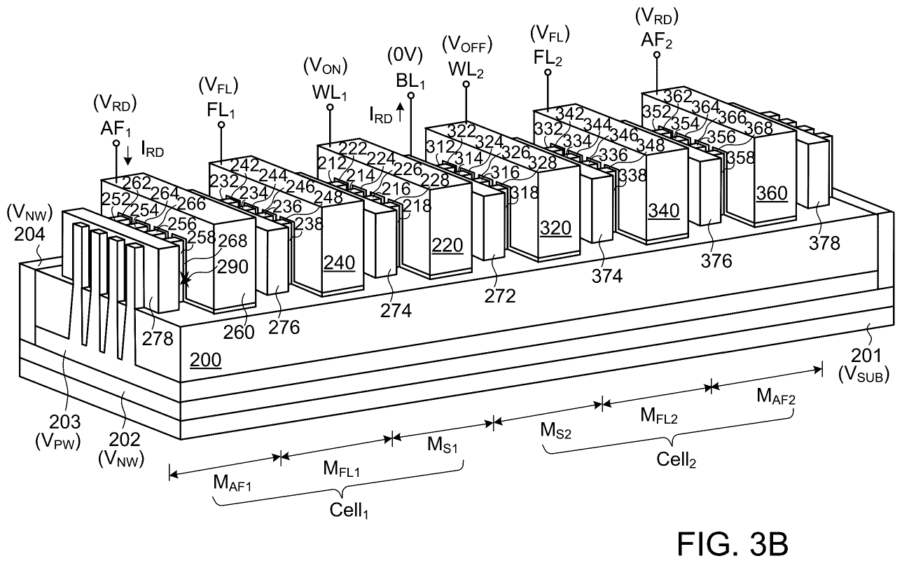

FIG. 3A schematically illustrates associated bias voltages for performing a program action on the memory cells of the antifuse-type memory according to the first embodiment of the present invention. FIG. 3B schematically illustrates associated bias voltages for performing a read action on the memory cells of the antifuse-type memory according to the first embodiment of the present invention. For allowing the antifuse-type memory of the present invention to receive a higher voltage (e.g., a higher program voltage V_{PP}) and operate normally, the semiconductor substrate 201 (sub) receives a substrate voltage V_{SUB} with a higher negative voltage value. For example, the substrate voltage V_{SUB} is in a range between −12V and −16V. The deep N-well region 202 (DNW) and the N-type pickup well region 204 (NW_{PU}) receive an N-well region voltage V_{NW}. For example, the N-well region voltage V_{NW} is in a range between 0.8V and 3V. The P-well region 203 (PW) receives a P-well region voltage V_{PW}. For example, the P-well region voltage V_{PW} is 0V.

Please refer to FIG. 3A. When the program action is performed, the antifuse control lines AF₁ and AF₂ receive the program voltage V_{PP}, the following control lines FL₁ and FL₂ receive a conducting voltage V_{FL}, the bit line BL₁ receives a ground voltage (0V), the word line WL₁ receives an on voltage V_{ON}, and the word line WL₂ receives an off voltage V_{OFF}. For example, the program voltage V_{PP} is in a range between 3V and 6V, the on voltage V_{ON} is in a range between 0.4V and 3V, and the magnitude of the conducting voltage V_{FL} is higher than or equal to the on voltage V_{ON}. Moreover, the deep N-well region 202 can be biased with the same voltage level of the on voltage V_{ON}.

When the program action is performed, the select transistor M_{S1} of the memory cell Cell₁ is turned on, and the following transistor M_{FL1} is in a conducting state. The ground voltage of the bit line BL₁ is transmitted to the drain/source contact layer 276 of the antifuse transistor M_{AF1} through the following transistor M_{FL1} and the select transistor M_{S1}. When the antifuse control line AF₁ receives the program voltage V_{PP}, the voltage stress between the fins 252, 254, 256, 258 and the gate structure 260 of the antifuse transistor M_{AF1} is equal to the program voltage V_{PP}. Under this circumstance, one of the gate dielectric layers 262, 264, 266 and 268 of the antifuse transistor M_{AF1} is ruptured. For example, in case that the gate dielectric layer 268 is ruptured, the region between the gate layer 260 and the fin 258 of the antifuse transistor M_{AF1} has a low resistance value. Consequently, the program current I_{PGM} generated by the memory cell Cell₁ is transmitted from antifuse control line AF₁ to the fin 258 through the gate layer 260 and the ruptured point 290 of the gate dielectric layer 268, and then the program current I_{PGM} flows to the bit line BL₁ through the following transistor M_{FL1} and the select transistor M_{S1}. In other words, the memory cell Cell₁ is programmed into the low-resistance storage state.

Moreover, since the select transistor M_{S2} of the memory cell Cell₂ is turned off, no voltage stress is applied to the region between the fins 352, 354, 356, 358 and the gate layer 360 of the antifuse transistor M_{AF2}. Consequently, the gate dielectric layers 362, 364, 366 and 368 of the antifuse transistor M_{AF2} are not ruptured. The region between the gate layer 360 and the fins 352, 354, 356, 358 of the antifuse transistor M_{AF2} has a high resistance value. In other words, the memory cell Cell₂ does not generate the program current. Consequently, the memory cell Cell₂ is maintained in the high-resistance storage state.

Please refer to FIG. 3B. When the read action is performed, the storage state of the memory cell Cell₁ can be judged. Meanwhile, the antifuse control lines AF₁ and AF₂ receive a read voltage V_{RD}, the following control lines FL₁ and FL₂ receive the conducting voltage V_{FL}, the bit line BL₁ receives the ground voltage (0V), the word line WL₁ receives the on voltage V_{ON}, and the word line WL₂ receives the off voltage V_{OFF}. For example, the read voltage V_{RD} is in a range between 0.5V and 2V.

When the read action is performed, the select transistor M_{S1} of the memory cell Cell₁ is turned on, and the following transistor M_{FL1} is in the conducting state. Since the memory cell Cell₁ is in the low-resistance storage state, a higher read current I_{RD} is generated by the memory cell Cell₁. The read current I_{RD} is transmitted from the antifuse control line AF₁ to the fin 258 through the gate layer 260 and the ruptured point 290 of the gate dielectric layer 268, and then the read current I_{RD} flows to the bit line BL₁ through the following transistor M_{FL1} and the select transistor M_{S1}.

Similarly, when the read action is performed, the storage state of the memory cell Cell₂ can be judged. Meanwhile, since the word line WL₁ receives the off voltage V_{OFF} and the word line WL₂ receives the on voltage V_{ON}, the read current generated by the memory cell Cell₂ flows to the bit line BL₁. Since the memory cell Cell₂ is in the high-resistance storage state, the read current generated by the memory cell Cell₂ is very low (e.g., nearly zero).

In other words, when the read action is performed, the storage state of the memory cell is determined as the high-resistance storage state or the low-resistance storage state according to the magnitude of read current I_{RD} generated by the memory cell. For example, a current comparator is provided. The current comparator receives a reference current and the read current I_{RD}. If the read current I_{RD} is higher than the reference current, the storage state of the memory cell (e.g., the memory cell Cell₁) is determined as the low-resistance storage state. Whereas, if the read current I_{RD} is lower than the reference current, the memory cell (e.g., the memory cell Cell₂) is determined as the high-resistance storage state.

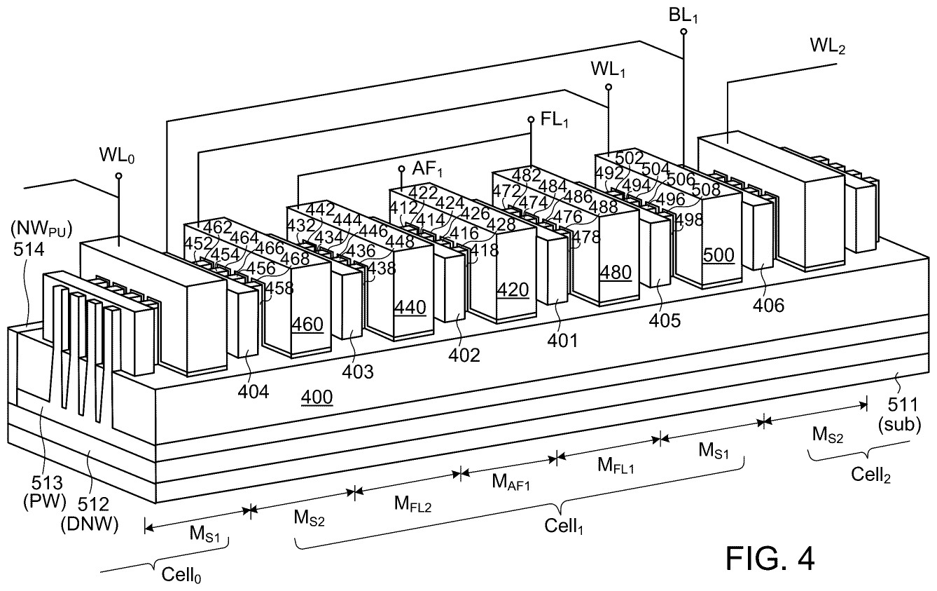

FIG. 4 is a schematic perspective view illustrating an antifuse-type memory according to a second embodiment of the present invention. As shown in FIG. 4, the antifuse-type memory comprises three memory cells Cell₀, Cell₁ and Cell₂. Like the structure of FIG. 1K, the FinFET transistors of the three memory cells Cell₀, Cell₁ and Cell₂ are constructed over a P-well region (PW) 513 within a semiconductor substrate (sub) 511 and enclosed by a pickup N-well region (NW_{PU}) 514. Furthermore, the lateral side of the P-well region (PW) 513 is contacted with the pickup N-well region (NW_{PU}) 514, and the bottom side of the P-well region (PW) 513 is contacted with a deep N-well region (DNW) 512. The pickup N-well region (NW_{PU}) 514 and the deep N-well region (DNW) 512 are collaboratively formed as the N-type region of the well structure. The P-well region (PW) 513 is formed as the P-type region of the well structure. That is, the lateral side and the bottom side of the P-type region of the well structure are enclosed by the N-type region of the well structure. In addition, the region that is arranged between the pickup N-well region (NW_{PU}) 514 and the FinFET transistor and located over the P-well region (PW) 513 is covered by an isolation layer 400.

As shown in FIG. 4, the three memory cells Cell₀, Cell₁ and Cell₂ of the antifuse-type memory are formed as a 3×1 array structure. The array structure is constructed over the P-well region (PW) 513 within the semiconductor substrate (sub) 511 and enclosed by the pickup N-well region (NW_{PU}) 514. The structure of the three memory cells Cell₀, Cell₁ and Cell₂ are identical. For succinctness, only the entire of the memory cell Cell₁ and portions of the memory cells Cell₀ and Cell₂ are shown in FIG. 4.

As shown in FIG. 4, the memory cell Cell₁ comprises five FinFET transistors. The structure of each of the five FinFET transistors is similar to that of FIG. 1K, and not redundantly described herein. In this embodiment, the memory cell Cell₁ comprises a select transistor M_{S1}, a select transistor M_{S2}, a following transistor M_{FL1}, a following transistor M_{FL2} and an antifuse transistor M_{AF1}.

In the memory cell Cell₁, the select transistor M_{S1} comprises a drain/source contact layer 406, a drain/source contact layer 405, a gate structure and four fins 492, 494, 496 and 498. The gate structure covers the top surfaces and the lateral surfaces of the central regions of the fins 492, 494, 496 and 498. The gate structure comprises four gate dielectric layers 502, 504, 506, 508 and a gate layer 500. The gate dielectric layers 502, 504, 506 and 508 cover the top surfaces and the lateral surfaces of the central regions of the fins 492, 494, 496 and 498, respectively. The gate layer 500 covers the gate dielectric layers 502, 504, 506 and 508. The drain/source contact layer 406 is electrically contacted with the top surfaces and the lateral surfaces of the first side regions of the fins 492, 494, 496 and 498. The drain/source contact layer 405 is electrically contacted with the top surfaces and the lateral surfaces of the second side regions of the fins 492, 494, 496 and 498. In other words, the first terminals of the fins 492, 494, 496 and 498 are electrically connected with the drain/source contact layer 406, and the second terminals of the fins 492, 494, 496 and 498 are electrically connected with the drain/source contact layer 405. Moreover, the drain/source contact layer 406 is connected with a bit line BL₁, and the gate layer 500 is connected with a word line WL₁.

The select transistor M_{S2} comprises a drain/source contact layer 403, a drain/source contact layer 404, a gate structure and four fins 452, 454, 456 and 458. The gate structure covers the top surfaces and the lateral surfaces of the central regions of the fins 452, 454, 456 and 458. The gate structure comprises four gate dielectric layers 462, 464, 466, 468 and a gate layer 460. The gate dielectric layers 462, 464, 466 and 468 cover the top surfaces and the lateral surfaces of the central regions of the fins 452, 454, 456 and 458, respectively. The gate layer 460 covers the gate dielectric layers 452, 454, 456 and 458. The drain/source contact layer 403 is electrically contacted with the top surfaces and the lateral surfaces of the first side regions of the fins 452, 454, 456 and 458. The drain/source contact layer 404 is electrically contacted with the top surfaces and the lateral surfaces of the second side regions of the fins 452, 454, 456 and 458. In other words, the first terminals of the fins 452, 454, 456 and 458 are electrically connected with the drain/source contact layer 403, and the second terminals of the fins 452, 454, 456 and 458 are electrically connected with the drain/source contact layer 404. Moreover, the drain/source contact layer 404 is connected with the bit line BL₁, and the gate layer 460 is connected with the word line WL₁.

The following transistor M_{FL1} comprises the drain/source contact layer 405, a drain/source contact layer 401, a gate structure and four fins 472, 474, 476 and 478. The gate structure covers the top surfaces and the lateral surfaces of the central regions of the fins 472, 474, 476 and 478. The gate structure comprises four gate dielectric layers 482, 484, 486, 488 and a gate layer 480. The gate dielectric layers 482, 484, 486 and 488 cover the top surfaces and the lateral surfaces of the central regions of the fins 472, 474, 476 and 478, respectively. The gate layer 480 covers the gate dielectric layers 482, 484, 486 and 488. The drain/source contact layer 405 is electrically contacted with the top surfaces and the lateral surfaces of the first side regions of the fins 472, 474, 476 and 478. The drain/source contact layer 401 is electrically contacted with the top surfaces and the lateral surfaces of the second side regions of the fins 472, 474, 476 and 478. In other words, the first terminals of the fins 472, 474, 476 and 478 are electrically connected with the drain/source contact layer 405, and the second terminals of the fins 472, 474, 476 and 478 are electrically connected with the drain/source contact layer 401. Moreover, the gate layer 480 is connected with a following control line FL₁.

The following transistor M_{FL2} comprises the drain/source contact layer 402, a drain/source contact layer 403, a gate structure and four fins 432, 434, 436 and 438. The gate structure covers the top surfaces and the lateral surfaces of the central regions of the fins 432, 434, 436 and 438. The gate structure comprises four gate dielectric layers 442, 444, 446, 448 and a gate layer 440. The gate dielectric layers 442, 444, 446 and 448 cover the top surfaces and the lateral surfaces of the central regions of the fins 432, 434, 436 and 438, respectively. The gate layer 440 covers the gate dielectric layers 442, 444, 446 and 448. The drain/source contact layer 402 is electrically contacted with the top surfaces and the lateral surfaces of the first side regions of the fins 432, 434, 436 and 438. The drain/source contact layer 403 is electrically contacted with the top surfaces and the lateral surfaces of the second side regions of the fins 432, 434, 436 and 438. In other words, the first terminals of the fins 432, 434, 436 and 438 are electrically connected with the drain/source contact layer 402, and the second terminals of the fins 432, 434, 436 and 438 are electrically connected with the drain/source contact layer 403. Moreover, the gate layer 440 is connected with the following control line FL₁.

The antifuse transistor M_{AF1} comprises the drain/source contact layer 401, a drain/source contact layer 402, a gate structure and four fins 412, 414, 416 and 418. The gate structure covers the top surfaces and the lateral surfaces of the central regions of the fins 412, 414, 416 and 418. The gate structure comprises four gate dielectric layers 422, 424, 426, 428 and a gate layer 420. The gate dielectric layers 422, 424, 426 and 428 cover the top surfaces and the lateral surfaces of the central regions of the fins 412, 414, 416 and 418, respectively. The gate layer 420 covers the gate dielectric layers 422, 424, 426 and 428. The drain/source contact layer 401 is electrically contacted with the top surfaces and the lateral surfaces of the first side regions of the fins 412, 414, 416 and 418. The drain/source contact layer 402 is electrically contacted with the top surfaces and the lateral surfaces of the second side regions of the fins 412, 414, 416 and 418. In other words, the first terminals of the fins 412, 414, 416 and 418 are electrically connected with the drain/source contact layer 401, and the second terminals of the fins 412, 414, 416 and 418 are electrically connected with the drain/source contact layer 402. Moreover, the gate layer 420 is connected with an antifuse control line AF₁.

The structure of each of the memory cell Cell₀ and Cell₂ is identical to the structure of the memory cell Cell₁. That is, each of the memory cells Cell₀ and Cell₂ comprises five FinFET transistors. The select transistor M_{S1} of the memory cell Cell₀ is connected with a word line WL₀. The select transistor M_{S2} of the memory cell Cell₂ is connected with a word line WL₂. The connecting relationships between associated transistors of each of the memory cells Cell₀ and Cell₂ are similar to the connecting relationships between associated transistors of the memory cell Cell₁, and not redundantly described herein.

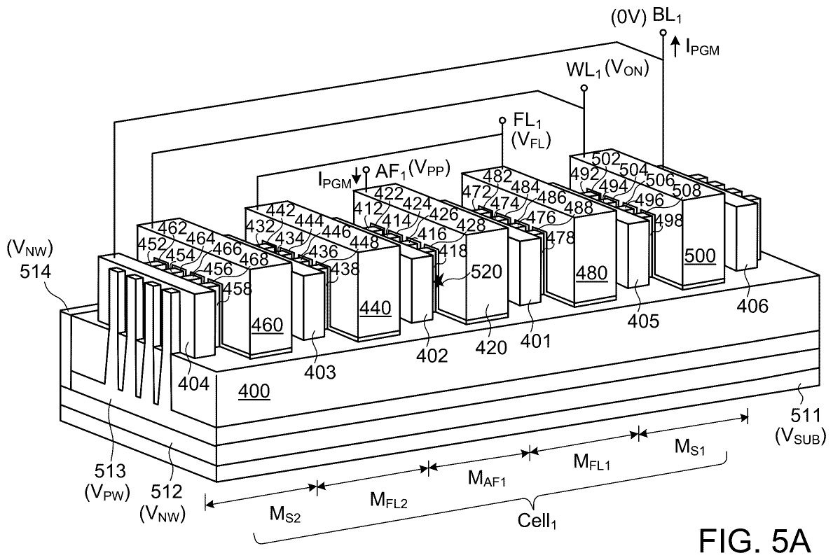

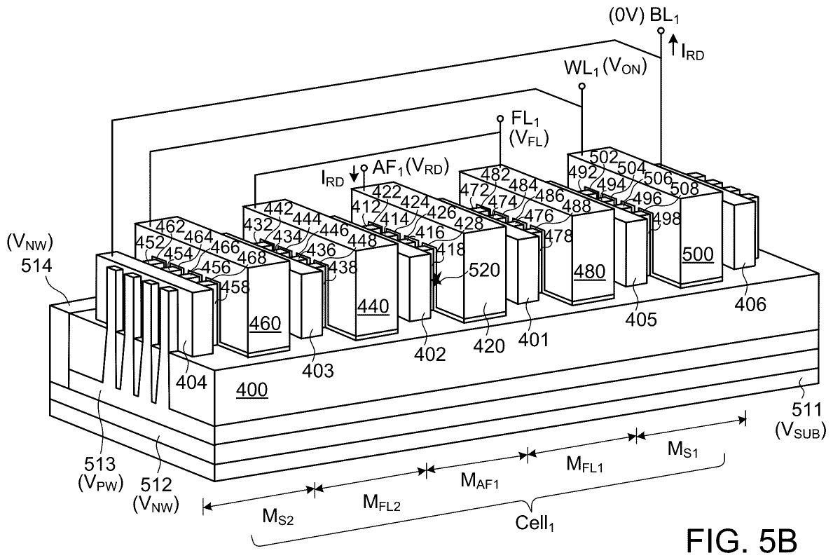

FIG. 5A schematically illustrates associated bias voltages for performing a program action on the memory cells of the antifuse-type memory according to the second embodiment of the present invention. FIG. 5B schematically illustrates associated bias voltages for performing a read action on the memory cells of the antifuse-type memory according to the second embodiment of the present invention. For allowing the antifuse-type memory of the present invention to receive a higher voltage (e.g., a higher program voltage V_{PP}) and operate normally, the semiconductor substrate 511 (sub) receives a substrate voltage V_{SUB} with a higher negative voltage value. For example, the substrate voltage V_{SUB} is in a range between −12V and −16V. The deep N-well region 512 (DNW) and the N-type pickup well region 514 (NW_{PU}) receive an N-well region voltage V_{NW}. For example, the N-well region voltage V_{NW} is in a range between 0.8V and 3V. The P-well region 513 (PW) receives a P-well region voltage V_{PW}. For example, the P-well region voltage V_{PW} is 0V.

Please refer to FIG. 5A. When the program action is performed, the antifuse control lines AF₁ receives the program voltage V_{PP}, the following control line FL₁ receives the conducting voltage V_{FL}, the bit line BL₁ receives a ground voltage (0V), and the word line WL₁ receives an on voltage V_{ON}. For example, the program voltage V_{PP} is in a range between 3V and 6V, the on voltage V_{ON} is in a range between 0.4V and 3V, and the magnitude of the conducting voltage V_{FL} is higher than or equal to the magnitude of the on voltage V_{ON}. Moreover, the deep N-well region 512 can be biased with the same voltage level of the on voltage V_{ON}.

When the program action is performed, the select transistors M_{S1} and M_{S2} of the memory cell Cell₁ are turned on, and the following transistors M_{FL1} and M_{FL2} are in a conducting state. The ground voltage (0V) of the bit line BL₁ is transmitted to the two drain/source contact layers 401 and 402 of the antifuse transistor M_{AF1} through the following transistors M_{FL1} and M_{FL2} and the select transistors M_{S1} and M_{S2}. When the antifuse control line AF₁ receives the program voltage V_{PP}, the voltage stress between the fins 412, 414, 416, 418 and the gate structure 420 of the antifuse transistor M_{AF1} is equal to the program voltage V_{PP}. Under this circumstance, one of the gate dielectric layers 422, 424, 426 and 428 of the antifuse transistor M_{AF1} is ruptured. For example, in case that the gate dielectric layer 428 is ruptured, the region between the gate layer 420 and the fin 418 of the antifuse transistor M_{AF1} has a low resistance value. Consequently, the program current I_{PGM} generated by the memory cell Cell₁ is transmitted from antifuse control line AF₁ to the fin 418 through the gate layer 420 and the ruptured point 520 of the gate dielectric layer 428, and then the program current I_{PGM} flows to the bit line BL₁ through the following transistor M_{FL1} and M_{FL2} and the select transistors M_{S1} and M_{S2}. In other words, the memory cell Cell₁ is programmed into the low-resistance storage state.

Whereas, if the word line WL₁ receives the off voltage V_{OFF} (e.g., 0V) when the program action is performed, the select transistors M_{S1} and M_{S2} of the memory cell Cell₁ are turned off. Under this circumstance, the memory cell Cell₁ does not generate the program current. Consequently, the memory cell Cell₁ is maintained in the high-resistance storage state.

Please refer to FIG. 5B. When the read action is performed, the storage state of the memory cell Cell₁ can be judged. Meanwhile, the antifuse control lines AF₁ receive a read voltage V_{RD}, the following control lines FL₁ receives the conducting voltage V_{FL}, the bit line BL₁ receives the ground voltage (0V), and the word line WL₁ receives the on voltage V_{ON}. For example, the read voltage V_{RD} is in a range between 0.5V and 2V.

When the read action is performed, the select transistors M_{S1} and M_{S2} of the memory cell Cell₁ are turned on, and the following transistors M_{FL1} and M_{FL2} are in the conducting state. Since the memory cell Cell₁ is in the low-resistance storage state, a higher read current I_{RD} is generated by the memory cell Cell₁. The read current I_{RD} is transmitted from the antifuse control line AF₁ to the fin 418 through the gate layer 420 and the ruptured point 520 of the gate dielectric layer 428, and then the read current I_{RD} flows to the bit line BL₁ through the following transistors M_{FL1} and M_{FL2} and the select transistors M_{S1} and M_{S2}. Since the read current I_{RD} is higher, the storage state of the memory cell Cell₁ is determined as the high-resistance storage state.

Whereas, if the gate dielectric layers 422, 424, 426 and 428 of the memory cell Cell₁ are not ruptured, when the read action is performed, the read current generated by the memory cell Cell₁ is very low (e.g., nearly zero). Consequently, the storage state of the memory cell Cell₁ is determined as the high-resistance storage state.

From above descriptions, the present invention provides an antifuse-type memory. The memory cell of the antifuse-type memory comprises FinFET transistors. Moreover, the FinFET transistors are served as the antifuse transistor in the memory cell. When the program action is performed, the voltage stress (e.g., the program voltage V_{PP}) is withstood by the gate dielectric layer between the gate layer and the fin of the antifuse transistor. In response to the high voltage stress, the gate dielectric layer of the antifuse transistor is ruptured, and the program action is completed. Moreover, the well structure of the present invention is specially designed. Consequently, the antifuse transistor can receive the high voltage (e.g., the program voltage V_{PP}) and operate normally. In the above embodiments of the present invention, the memory cells are constructed over a P-well region (PW) within a semiconductor substrate (sub) and enclosed by a pickup N-well region (NW_{PU}). Furthermore, the lateral side of the P-well region (PW) is contacted with the pickup N-well region (NW_{PU}), and the bottom side of the P-well region (PW) is contacted with a deep N-well region (DNW). The lateral side and the bottom side of the P-type region of the well structure are enclosed by the N-type region of the well structure.

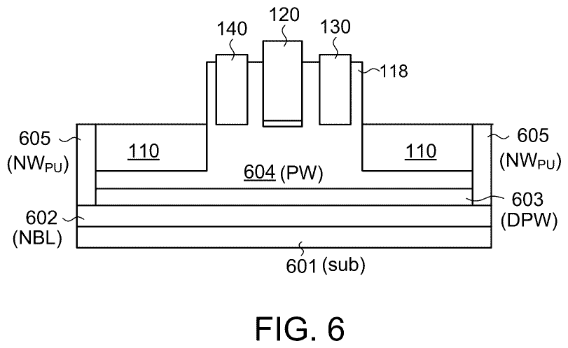

It is noted that the example of the well structure is not restricted. That is, the well structure may be modified according to the practical requirements. FIG. 6 is a schematic cross-sectional view illustrating another exemplary well structure of the antifuse-type memory. The FinFET transistor as shown in FIG. 6 is similar to the FinFET transistor as shown in FIG. 1L. In comparison with the FinFET transistor of FIG. 1L, the well structure of the FinFET transistor of FIG. 6 and is distinguished. For succinctness, only the well region of FIG. 6 will be described as follows.

The well structure is formed within the semiconductor substrate (sub) 601. For example, the semiconductor substrate (sub) 601 is a P-substrate. The well structure comprises an N-type region and a P-type region. The lateral sides and the bottom side of the P-type region are contacted with the N-type region. In addition, the lateral sides and the bottom side of the P-type region are enclosed by the N-type region. The FinFET transistors of the memory cell are installed on the region that is located over the surface of the P-well region and enclosed by the N-type region. Moreover, the N-type region comprises an N buried layer (NBL) and a pickup N-well region (NW_{PU}) 605, and the P-type region comprises a P-well region (PW) 604 and a deep P-well (DPW) 603.

Please refer to FIG. 6 again. The bottom side of the P-well region (PW) 604 is contacted with the deep P-well region (DPW) 603. The P-well region (PW) 604 and the deep N-well region (DNW) 603 are collaboratively formed as the P-type region of the well structure. Moreover, the pickup N-well region (NW_{PU}) 605 surrounds the P-well region (PW) 604 and the deep P-well region (DPW) 603. The pickup N-well region (NW_{PU}) 605 is contacted with the lateral sides of the P-well region (PW) 604 and the deep P-well region (DPW) 603. Moreover, the bottom side of the deep P-well region (DPW) 603 is contacted with the N buried layer (NBL) 602. The bottom side of the pickup N-well region (NW_{PU}) 605 is contacted with the N buried layer 602 (NBL). The top side of the pickup N-well region 605 (NW_{PU}) is exposed to the surface of the semiconductor substrate (sub) 601.

In the first embodiment, the memory cell Cell₁ comprises three FinFET transistors. In the second embodiment, the memory cell Cell₁ comprises five FinFET transistors. It is noted that the types of the transistors in the antifuse-type memory are not restricted. For example, in some other embodiments, the antifuse transistor of the memory cell Cell₁ is a FilnFET transistor, and the other transistors of the memory cell Cell₁ are other types of transistors. In a variant example of the memory cell Cell₁ in the first embodiment, two general planar fin field-effect transistors (planar FETs) are used as the select transistor M_{S1} and the following transistor M_{FL1}, and one FinFET transistor is used as the antifuse transistor M_{AF1}. In other words, the first drain/source terminal of the select transistor M_{S1} is connected with the bit line BL₁, and the gate terminal of the select transistor M_{S1} is connected with the word line WL₁. The first drain/source terminal of the following transistor M_{FL1} is connected with the second drain/source terminal of the select transistor M_{S1}, and the gate terminal of the following transistor M_{FL1} is connected with the following line FL₁. The drain/source contact layer 276 of the antifuse transistor M_{AF1} is connected with the second drain/source terminal of the following transistor M_{FL1}, and the gate layer 260 of the antifuse transistor M_{AF1} is connected with the antifuse control line AF₁.

As mentioned above, the present invention provides an antifuse-type memory with fin field-effect (FinFET) transistors. Since the antifuse transistor receives the higher operation voltage, the well structure in the semiconductor substrate is specially designed. Moreover, the semiconductor substrate is biased with a substrate voltage with a higher negative voltage value. Consequently, the antifuse transistor can be operated at the high operation voltage.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. An antifuse-type memory comprising a first memory cell, the first memory cell being constructed on a semiconductor substrate, the first memory cell comprising:
a first select transistor, wherein a first drain/source terminal of the first select transistor is connected with a first bit line, and a gate terminal of the first select transistor is connected with a first word line;
a first following transistor, wherein a first drain/source terminal of the first following transistor is connected with a second drain/source terminal of the first select transistor, and a gate terminal of the first following transistor is connected with a first following control line; and
a first antifuse transistor comprising:
a first fin;
a first gate structure comprising a first gate dielectric layer and a first gate layer, wherein the first gate dielectric layer covers a top surface and two lateral surfaces of a central region of the first fin, the first gate dielectric layer is covered by the first gate layer, and the first gate layer is connected with a first antifuse control line;
a first drain/source contact layer electrically connected with a first terminal of the first fin, wherein the first drain/source contact layer is connected with a second drain/source terminal of the first following transistor; and
a second drain/source terminal electrically connected with a second terminal of the first fin,
wherein the first bit line receives a ground voltage, the first word line receives an on voltage, the first following control line receives a conducting voltage and the first antifuse control line receives a program voltage when a program action is performed, the first gate dielectric layer of the first antifuse transistor is ruptured, so that the first memory cell is programmed into a low-resistance storage state.

2. The antifuse-type memory as claimed in claim 1, wherein the first select transistor comprises:
a third drain/source contact layer connected with the first bit line;
a fourth drain/source contact layer;
a second fin, wherein a first terminal of the second fin is electrically connected with the third drain/source contact layer, and a second terminal of the second fin is electrically connected with the fourth drain/source contact layer; and
a second gate structure comprising a second gate dielectric layer and a second gate layer, wherein the second gate dielectric layer covers a top surface and two lateral surfaces of a central region of the second fin, the second gate dielectric layer is covered by the second gate layer, and the second gate layer is connected with the first word line.

3. The antifuse-type memory as claimed in claim 2, wherein the first following transistor comprises:
the fourth drain/source contact layer;
the first drain/source contact layer;
a third fin, wherein a first terminal of the third fin is electrically connected with the fourth drain/source contact layer, and a second terminal of the third fin is electrically connected with the first drain/source contact layer; and
a third gate structure comprising a third gate dielectric layer and a third gate layer, wherein the third gate dielectric layer covers a top surface and two lateral surfaces of a central region of the third fin, the third gate dielectric layer is covered by the third gate layer, and the third gate layer is connected with the first following control line.

4. The antifuse-type memory as claimed in claim 3, wherein the antifuse-type memory further comprises a dummy FinFET transistor, and the dummy FinFET transistor comprises:
the second drain/source contact layer;
a fifth drain/source contact layer;
a fourth fin, wherein a first terminal of the fourth fin is electrically connected with the second drain/source contact layer, and a second terminal of the fourth fin is electrically connected with the fifth drain/source contact layer; and
a fourth gate structure comprising a fourth gate dielectric layer and a fourth gate layer, wherein the fourth gate dielectric layer covers a top surface and two lateral surfaces of a central region of the fourth fin, and the fourth gate dielectric layer is covered by the fourth gate layer.

5. The antifuse-type memory as claimed in claim 3, wherein the first memory cell further comprises a second select transistor and a second following transistor,
wherein the second following transistor comprises:
the second drain/source contact layer;
a fifth drain/source contact lay;
a fourth fin, wherein a first terminal of the fourth fin is electrically connected with the second drain/source contact layer, and a second terminal of the fourth fin is electrically connected with the fifth drain/source contact layer; and
a fourth gate structure comprising a fourth gate dielectric layer and a fourth gate layer, wherein the fourth gate dielectric layer covers a top surface and two lateral surfaces of a central region of the fourth fin, the fourth gate dielectric layer is covered by the fourth gate layer, and the fourth gate layer is connected with the first following control line;
wherein the second select transistor comprises:
the fifth drain/source contact layer;
a sixth drain/source contact layer connected with the first bit line;
a fifth fin, wherein a first terminal of the fifth fin is electrically connected with the fifth drain/source contact layer, and a second terminal of the fifth fin is electrically connected with the sixth drain/source contact layer; and
a fifth gate structure comprising a fifth gate dielectric layer and a fifth gate layer; wherein the fifth gate dielectric layer covers a top surface and two lateral surfaces of a central region of the fifth fin, the fifth gate dielectric layer is covered by the fifth gate layer, and the fifth gate layer is connected with the first bit line.

6. The antifuse-type memory as claimed in claim 1, wherein the first bit line receives the ground voltage, the first word line receives an off voltage, the first following control line receives the conducting voltage and the first antifuse control line receives the program voltage when the program action is performed, the first gate dielectric layer of the first antifuse transistor is not ruptured, so that the first memory cell is programmed into a high-resistance storage state.

7. The antifuse-type memory as claimed in claim 6, wherein when a read action is performed, the first bit line receives the ground voltage, the first word line receives the on voltage, the first following control line receives the conducting voltage and the first antifuse control line receives a read voltage, so that the first memory cell generates a read current to the first bit line, wherein a storage state of the memory cell is determined as the high-resistance storage state or the low-resistance storage state according to a magnitude of read current.

8. The antifuse-type memory as claimed in claim 7, wherein if the read current is lower than a reference current, the first memory cell is in the high-resistance storage state, wherein if the read current is higher than the reference current, the first memory cell is in the low-resistance storage state.

9. The antifuse-type memory as claimed in claim 1, wherein the semiconductor substrate comprises a well structure, and the well structure comprises a first type region and a second type region, wherein a lateral side and a bottom side of the first type region are contacted with the second type region, and the lateral sides and the bottom side of the first type region are enclosed by the second type region, wherein the first select transistor, the first following transistor, the first antifuse transistor are constructed over the first type region.

10. The antifuse-type memory as claimed in claim 9, wherein the first type region is a P-type region, and the second type region is an N-type region, wherein the P-type region is a P-well region, and the N-type region comprises a deep N-well region and a pickup N-well region, wherein the pickup N-well region surrounds the P-well region, a top side of the pickup N-well region is exposed to a surface of the semiconductor substrate, a bottom side of the pickup N-well region is contacted with the deep N-well region, the lateral side of the P-well region is contacted with the pickup N-well region, and a bottom side of the P-well region is contacted with the deep N-well region.

11. The antifuse-type memory as claimed in claim 9, wherein the first type region is a P-type region, and the second type region is an N-type region, wherein the P-type region comprises a P-well region and a deep P-well region, and the N-type region comprises an N buried region and a pickup N-well region, wherein a bottom side of the P-well region is contacted with the deep P-well region, the pickup N-well region surrounds the P-well region and the deep P-well region, a top side of the pickup N-well region is exposed to a surface of the semiconductor substrate, a bottom side of the pickup N-well region is contacted with the N buried region, a lateral side of the P-well region and a lateral side of the deep P-well region are contacted with the pickup N-well region, and a bottom side of the P-well region is contacted with the N buried region.

12. The antifuse-type memory as claimed in claim 1, wherein the semiconductor substrate receives a substrate voltage with a negative voltage value.
